(19) United States
(12) Patent Application Publication
(10) Pub. No.: US 2026/0040470 A1
(43) Pub. Date: Feb. 5, 2026

(54) DISPLAY DEVICE, ELECTRONIC DEVICE AND VEHICLE

(71) Applicant: Samsung Display Co., LTD., Yongin-si (KR)

(72) Inventor: Sung Hwan PARK, Yongin-si (KR)

(21) Appl. No.: 19/077,842

(22) Filed: Mar. 12, 2025

(30) Foreign Application Priority Data
Aug. 5, 2024 (KR) 10-2024-0103937

(51) Int. Cl. H05K 5/03; B60K 35/50; H10K 59/80

(52) U.S. Cl. CPC H05K 5/03; H10K 59/873; H10K 59/8792; B60K 35/50

(57) ABSTRACT

A display device includes a display panel, a window region disposed on a top surface of the display panel, and a reinforcing structure that includes a first portion covering a lateral surface of the display panel and a second portion disposed under a bottom surface of the display panel.

This application claims priority to Korean Patent Application No. 10-2024-0103937, filed on Aug. 5, 2024, and all the benefits accruing therefrom under 35 U.S.C. § 119, the content of which in its entirety is herein incorporated by reference.

### BACKGROUND

### 1. Field

The invention relates to a display device, an electronic device and a vehicle.

### 2. Description of Related Art

Recently, with developments of automotive devices such as automobiles, mobile devices (such as a smartphone and a tablet), and media devices (such as a computer and TV), various display devices have been developed to be applied to the above devices

In the automotive device, the mobile device and/or the media device, an image may be displayed in a curved area. In this case, a display device may be provided as a curved display device.

However, cracks or an interlayer spacing of the display device may be caused at the curved area and/or an outside of the curved area that result in penetration of impurities from the outside or lift-off between the layers that are included within the display device.

### SUMMARY

According to an aspect of the invention, there is provided a display device having improved mechanical stability and life-span property.

According to an aspect of the invention, there is provided a method of manufacturing a display device having improved mechanical stability and life-span property.

According to an aspect of the invention, there is provided an electronic device including a display device with anti-shock property and stability.

According to an aspect of the invention, there is provided a vehicle including a display device with anti-shock property and stability.

In an embodiment, a display device includes a display panel, a window region disposed on a top surface of the display panel, and a reinforcing structure that includes a first portion covering a lateral surface of the display panel and a second portion disposed under a bottom surface of the display panel.

In an embodiment, the window region may include a window substrate including a transmissive area and a bezel area, and a light-shielding pattern arranged under the bezel area.

In an embodiment, the first portion may cover at least a portion of a bottom surface of the light-shielding pattern.

In an embodiment, the display device may further include a light control region interposed between the display panel and the window region.

In an embodiment, the first portion may cover a lateral surface of the light control region.

In an embodiment, the light control region may include an anti-reflection layer.

In an embodiment, the display device may further include a first adhesive layer interposed between the display panel and the window region.

In an embodiment, the first portion may cover a lateral surface of the first adhesive layer.

In an embodiment, the display device may further include a second adhesive layer and a connection structure sequentially arranged under a bottom surface of the second portion.

In an embodiment, the second adhesive layer may contact the bottom surface of the second portion and may not contact the display panel.

In an embodiment, the display device may further include a cover panel arranged under the bottom surface of the display panel. The second portion may cover at least a portion of a bottom surface of the cover panel.

In an embodiment, the display device may further include a second adhesive layer and a connection structure sequentially arranged under a bottom surface of the second portion. The second adhesive layer may be disposed directly under the bottom surface of the second portion and may not contact the cover panel.

In an embodiment, the reinforcing structure may include a resin including at least one selected from the group consisting of a Si-based compound and an acrylic-based compound.

In an embodiment, the display panel includes a base substrate, a circuit layer on the base substrate, and a light-emitting device electrically connected to the circuit layer.

In an embodiment, the light-emitting device includes a first electrode, a second electrode, and an intermediate layer including an emission layer disposed between the first electrode and the second electrode.

In an embodiment, an electronic device includes an electronic device frame, and the above-described display device coupled to the electronic device frame.

In an embodiment, the display device may further include a second adhesive layer and a connection structure sequentially arranged under a bottom surface of the second portion, and the display device may be coupled to the electronic device frame by the connection structure.

In an embodiment, the electronic device may be selected from a flat panel display, a curved display, a computer monitor, a medical monitor, a television, a billboard, an indoor or outdoor lighting, a signal light, a head-up display, a transparent display, a flexible display, a rollable display, a foldable display, a laser printer, a phone, a mobile phone, a tablet, a phablet, a personal information terminal (PDA), a wearable device, a laptop computer, a digital camera, a camcorder, a viewfinder, a 3D display, an electronic book, an electronic dictionary, an electronic notebook, an electronic sensor, a virtual reality or augmented reality display, a video wall, a theater or a stadium screen, or a health care device.

In an embodiment, a vehicle includes a vehicle frame, and the above-described display device coupled to the vehicle frame.

In an embodiment, the display device may further include a second adhesive layer and a connection structure sequentially arranged under a bottom surface of the second portion, and the display device may be coupled to the vehicle frame by the connection structure.

In a method of manufacturing a display device, according to an embodiment, a window region is formed on a display panel. A reinforcing structure that includes a first portion covering a lateral surface of the display panel and a second portion disposed under a bottom surface of the display panel is formed.

In an embodiment, a second adhesive layer and a connections structure may be sequentially formed under a bottom surface of the second portion.

In an embodiment, a cover panel may be further formed under the bottom surface of the display panel. The second portion may at least partially cover a bottom surface of the cover panel.

According to the above-described embodiments, the display device may include a reinforcing structure including a first portion covering a side surface of a display panel and a second portion disposed under a bottom surface of the display panel. Accordingly, penetration of impurities and moisture into the side surface of the display panel may be suppressed, and lift-off between the display panel and adjacent layers (e.g., a light control region, an adhesive layer, a cover panel, etc.) may be prevented. Thus, mechanical stability of the display device may be improved and life-span properties may be improved.

### BRIEF DESCRIPTION OF THE DRAWINGS

FIG. 1 is a plan view illustrating a display device, in accordance with an embodiment.

FIG. 2 is a cross-sectional view illustrating a display device, in accordance with an embodiment.

FIG. 3 is a cross-sectional view illustrating a display device, in accordance with an embodiment.

FIG. 4 is a cross-sectional view illustrating a display device, in accordance with an embodiment.

FIG. 5 is a cross-sectional view illustrating a display panel in accordance with example embodiments.

FIG. 6 is a cross-sectional view illustrating a display panel, in accordance with an embodiment.

FIG. 7 is a cross-sectional view illustrating a light-emitting device, in accordance with an embodiment.

FIG. 8 is a cross-sectional view illustrating a light-emitting device, in accordance with an embodiment.

FIG. 9 is a schematic view illustrating a vehicle to which a display device is employed, in accordance with an embodiment.

### DETAILED DESCRIPTION

According to embodiments, a display device including a display panel, a window region and a reinforcing structure is provided. Additionally, a vehicle including the display device is provided.

Hereinafter, embodiments of the invention will be described in more detail with reference to the attached drawings. The same reference numerals can be used for indicating the same elements in the drawings, and repeated descriptions of the same elements can be omitted. Embodiments disclosed in the attached drawings are exemplary, and are to be understood to include all modifications, equivalents and substitutes included in the spirit and technical scope of the invention.

The terms “on”, “over”, or “between” as used herein refers to a direct placement/connection/combination, and also refers to a case where another element is interposed two different elements.

The terms “upper”, “lower”, “first”, “second”, etc., are used in a relative sense to distinguish different elements or positions, and do not specify an absolute position or an absolute order.

The term “thickness direction” used herein may refer to a direction in which layers of the display device are stacked.

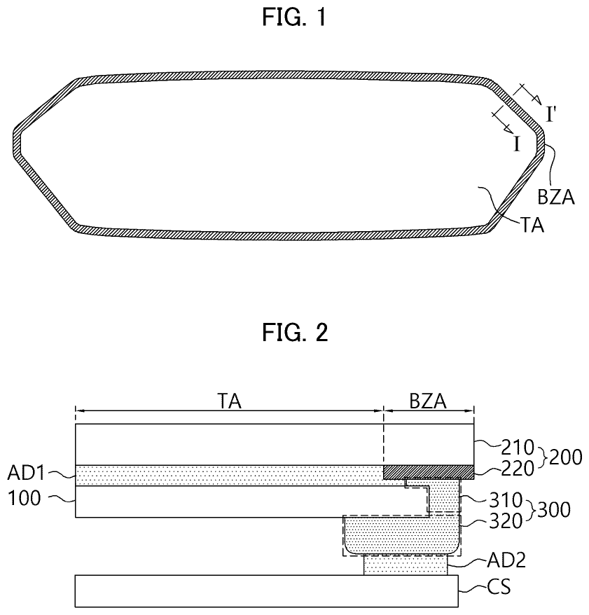

FIG. 1 is a plan view illustrating a display device, in accordance with an embodiment. FIG. 2 is a cross-sectional view illustrating a display device, in accordance with an embodiment. For example, FIG. 2 is a cross-sectional view taken along line I-I′ of FIG. 1 in a thickness direction.

In an embodiment and referring to FIGS. 1 and 2, the display device may include a display panel 100 and a window region 200 disposed on a top surface of the display panel 100.

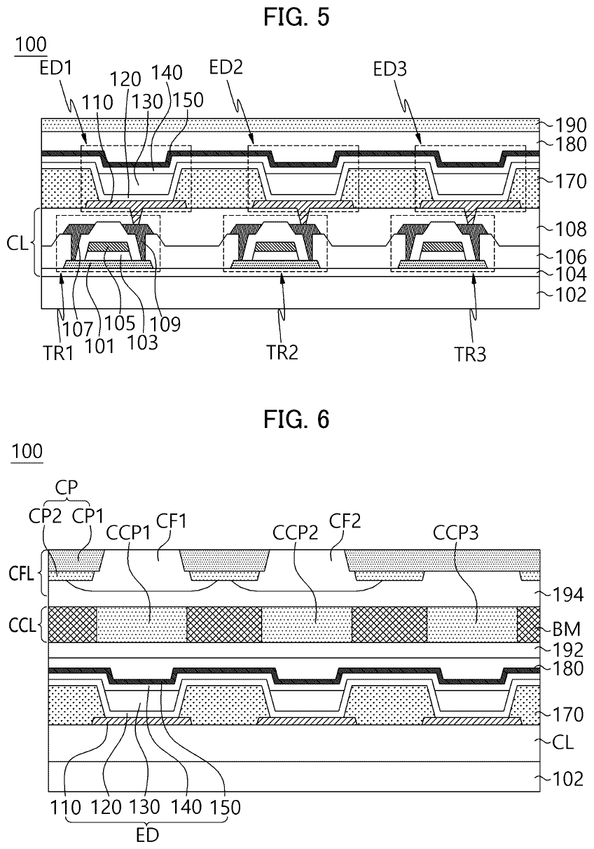

In an embodiment, the display panel 100 may include light-emitting devices that display an image of the display device and a circuit layer that applies a signal to the light-emitting devices. For example, the display panel 100 may be provided as an image display region of the display device. Detailed structures of the display panel 100 will be described later with reference to FIGS. 5 and 6.

In an embodiment, the window region 200 may be provided as a surface directly viewed by a user of the display device.

In an embodiment, the window region 200 may include a window substrate 210 including a transmissive area TA and a bezel area BZA, and a light-shielding pattern 220 disposed under the bezel area BZA.

In an embodiment, the transmissive area TA may serve as an area for displaying an image and overlapping the light-emitting devices of the display panel 100 in the thickness direction.

In an embodiment, the bezel area BZA may be provided as a non-display area of the display device or may be provided as an area displaying a predetermined color. For example, the bezel area BZA may not overlap the light-emitting devices of the display panel 100 in the thickness direction, and thus an image from the display panel 100 may not be visible in the bezel area BZA.

In an embodiment, the bezel area BZA may be disposed along a circumference of the transmissive area TA. Although FIG. 1 illustrates a structure in which the bezel area BZA surrounds the transmissive area TA, the invention is not limited thereto. For example, in another embodiment, the bezel area BZA may be in contact with only a partial side of the transmissive area TA.

In an embodiment, the window substrate 210 may include a polymer material such as polyimide, polysiloxane, an epoxy resin, an acrylic resin or polyester, or may include a glass substrate or a metal substrate.

Additionally, the window substrate 210 may serve as an image display surface that may be directly recognized by the user.

Furthermore, a thickness of the window substrate 210 may be in a range from about 0.3 mm to about 1.5 mm. In the above range, the display panel 100 may be sufficiently protected, and a thickness of the display device may be reduced. For example, the thickness of the window substrate 210 applied to a mobile electronic device may be in a range from about 0.3 mm to about 0.7 mm, and the thickness of the window substrate 210 applied to a vehicle may be in a range from about 1.0 mm to about 1.5 mm.

In an embodiment, the light-shielding pattern 220 may be disposed under the bezel area BZA. For example, the light-shielding pattern 220 may be disposed at an edge portion of the window region 200 and an image of the display panel 100 may not be displayed in the bezel area BZA through the light-shielding pattern 220. Accordingly, a metal structure or an opaque structure that can be visually recognized from an outside of the display device may be disposed under the light-shielding pattern 220 or the bezel area BZA to enhance sharpness and aesthetics of a displayed image.

In an embodiment, the light-shielding pattern 220 may include a pigment or a dye. For example, the light-shielding pattern 220 may be formed by printing an ink having a predetermined color on the window substrate 210.

In an embodiment, the light-shielding pattern 220 may be patterned to have a predetermined design or color.

In an embodiment, the light-shielding pattern 220 may serve as a black matrix.

For example, a thickness of the light-shielding pattern 220 may be smaller than that of the window substrate 210, where the thickness of the light-shielding pattern 220 may be in a range from about 5 mm to about 500 mm.

In an embodiment, an area of the window region 200 in a plan view may be larger than an area of the display panel 100 in the plan view. For example, a lateral surface of the display panel 100 may be closer to a center of the display device in the plan view than a lateral surface of the window region 200.

In an embodiment, the display device may include a reinforcing structure 300 including a first portion 310 covering the lateral surface of the display panel 100 and a second portion 320 disposed under a bottom surface of the display panel 100. Accordingly, penetration of impurities and moisture into the lateral surface of the display panel 100 may be suppressed, and lift-off between the display panel 100 and other layers (e.g., a light control region, a first adhesive layer AD1, a cover panel, etc.) may be prevented. Thus, mechanical stability of the display device may be improved and life-span properties may be improved.

In an embodiment, the first portion 310 and the second portion 320 may be formed as a substantially integral member using the same material. For example, the first portion 310 may extend to cover the lateral surface of the display panel 100, and the second portion 320 may be directly connected to one end portion of the first portion 310 to extend under the bottom surface of the display panel 100.

In an embodiment, the first portion 310 may cover at least a portion of the light-shielding pattern 220. Accordingly, a bottom surface of the window region 200, the lateral surface of the display panel 100 and the bottom surface of the display panel 100 may be protected by the reinforcing structure 300 from being penetrated by external impurities, and a binding force between components of the display device may be increased, thereby improving reliability.

In an embodiment, the reinforcing structure 300 may include a resin including an Si-based compound, an acrylic-based compound, etc. The resin may include an ultraviolet (UV) cured resin, a thermosetting resin, an UV and thermal hybrid cured resin, etc. The resin may include an electrostatic discharge (ESD) resin, an epoxy-based resin (e.g., a TUFFY resin), a gap filling resin, etc. The compound/resin may be used alone or in a combination of two or more therefrom.

In an embodiment, the resin may be injected into a lateral portion of the display device in a liquid or mold form to form the reinforcing structure 300. Accordingly, external exposure of the display panel and adjacent components (e.g., the light control region, the first adhesive layer AD1, the cover panel, etc.) may be further suppressed.

In an embodiment, the first adhesive layer AD1 may be disposed between the display panel 100 and the window region 200. Accordingly, structural stability of a stacked structure of the display device may be improved.

In an embodiment, the first adhesive layer AD1 may include an optically clear adhesive (OCA), an optically clear resin (OCR), etc. For example, an adhesive film such as an OCA film, an OCR film, etc., may be provided as the first adhesive layer AD1.

In an embodiment, the first portion 310 of the reinforcing structure 300 may cover a lateral surface of the first adhesive layer AD1. For example, the first portion 310 may commonly cover the lateral surface of the first adhesive layer AD1 and the lateral surface of the display panel 100. Thus, lifting between the first adhesive layer AD1 and the display panel 100 may be suppressed.

In an embodiment, a second adhesive layer AD2 and a connection structure CS may be sequentially disposed under a bottom surface of the second portion 320. For example, the connection structure CS and the reinforcing structure 300 may be connected to each other through the second adhesive layer AD2.

In an embodiment, the second adhesive layer AD2 may include substantially the same type of material as that of the first adhesive layer AD1.

In an embodiment, the connection structure CS may serve as an intermediate structure connecting the display device and an object to which the display device is applied. Structures and materials widely known in the related art may be used so that the intermediate structure may be capable of being connected or coupled to the object. For example, in an embodiment, the connection structure CS may include a composite structure in which a plurality of sub-connection units are combined.

In an embodiment, the connection structure CS may include a bracket connected to a frame of a vehicle or a media device, where a shape and a structure of the bracket may be properly adjusted according to the applied vehicle or media device.

In an embodiment, the second adhesive layer AD2 may contact a bottom surface of the second portion 320, and may not contact the display panel 100. Accordingly, damages to the display panel 100 due to detachment of an adhesive member caused by an external impact or bending of the display device may be reduced.

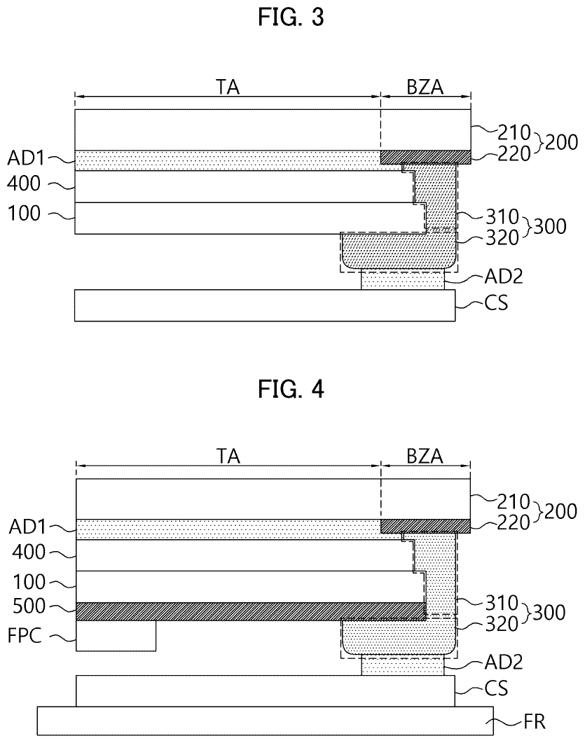

FIG. 3 is a cross-sectional view illustrating a display device, in accordance with an embodiment. For example, FIG. 3 is a view taken along a line I-I′ of FIG. 1 directed in a thickness direction.

In an embodiment and referring to FIG. 3, the display device may further include a light control region 400 disposed between the display panel 100 and the window region 200.

In an embodiment, the light control region 400 may include a multi-layered structure including a polarizing layer, an anti-reflection layer, etc.

In an embodiment, the light control region 400 may include the anti-reflection layer which may improve an image sharpness by controlling a reflected light from the display panel 100 by an external light source. Further, an image of the display device may be prevented from being reflected on a front window of a vehicle to which the display device is applied, so that driving stability may be achieved.

In an embodiment, a thickness of the light control region 400 may be in a range from about 330 μm to about 520 μm. In the above range, the reflected light may be sufficiently controlled, and the thickness of the display device may be reduced. For example, the thickness of the anti-reflection layer may be in a range from about 230 μm to about 270 μm, and a thickness of the polarization layer may be in a range from about 90 μm to about 250 μm.

In an embodiment, the first adhesive layer AD1 may be interposed between the light control region 400 and the window region 200.

In an embodiment, the display panel 100 and the light control region 400 may be stacked by an adhesive member (not illustrated). In this case, the first portion 310 of the reinforcing structure 300 may also cover a lateral surface of the adhesive member.

In an embodiment, the first portion 310 of the reinforcement structure 300 may cover a lateral surface of the light control region 400. For example, the first portion 310 may cover the lateral surface of the display panel 100, the lateral surface of the light control region 400, and the lateral surface of the first adhesive layer AD1 together to further suppress the interlayer lifting and the external impurity penetration.

FIG. 4 is a cross-sectional view illustrating a display device, in accordance with an embodiment. For example, FIG. 4 may be a cross-sectional view taken along a line I-I′ of FIG. 1 directed in a thickness direction.

In an embodiment and referring to FIG. 4, the display device may further include a cover panel 500 disposed under the bottom surface of the display panel 100.

In an embodiment, the cover panel 500 may include a material having an impact resistance property, an electromagnetic wave shielding property, a heat dissipation property, a barrier property, etc. The display panel 100 may be protected from an external impact by the cover panel 500, and image visibility of the display panel 100 may be improved.

In an embodiment, the cover panel 500 may have a single-layered structure.

In an embodiment, the cover panel 500 may have a multi-layered structure. For example, the cover panel 500 may include a stacked structure including a heat dissipation layer, a plastic foam, and/or a black sheet.

In an embodiment, the heat dissipation layer of the cover panel 500 may contain a metal such as Cu and Al to dissipate a heat generated from the display panel 100 to an outside.

Moreover, in an embodiment, the plastic foam may serve as a support structure of the cover panel 500.

In an embodiment, the black sheet may prevent an image emitted from the display panel 100 from being refracted or reflected below the display panel 100, thereby further improving the image sharpness of the display device.

In an embodiment, a total thickness of the cover panel 500 may be in a range from about 300 μm to about 550 μm. In the above range, an excessive increase in the thickness of the display device may be suppressed while sufficiently protecting the display panel 100.

In an embodiment, the second portion 320 of the reinforcement structure 300 may cover at least a portion of a bottom surface of the cover panel 500. Accordingly, mechanical stability of the stack structure including the display panel 100, the reinforcement structure 300 and the window region 200 may be further improved.

In an embodiment, the second portion 320 may extend along a bottom surface of the cover panel 500.

In an embodiment, the first portion 310 of the reinforcing structure 300 may cover a bottom surface of the light-shielding pattern 220, the lateral surface of the first adhesive layer AD1, the lateral surface of the light control region 400, the lateral surface of the display panel 100 and a lateral surface of the cover panel 500, and the second portion 320 may be integrally connected to the first portion 310 to cover at least a portion of the bottom surface of the cover panel 500. Thus, lift-off between the display panel 100, the light control region 400, the cover panel 500 and the first adhesive layer AD1 may be prevented, and the external impurities/moisture permeation may be suppressed.

In an embodiment, the second adhesive layer AD2 may contact a bottom surface of the second portion 320 and may not contact the cover panel 500. Accordingly, damages to the cover panel 500 and/or the display panel 100 due to detachment of the adhesive member caused by the external impact or bending of the display device may be suppressed.

In an embodiment, the reinforcing structure 300 may be formed along an edge portion of the display device, and the second adhesive layer AD2 may contact only a portion of the bottom surface of the second portion 320 of the reinforcing structure 300. For example, a plurality of the second adhesive layers AD2 may be formed to be spaced apart from each other along the edge of the display device. Accordingly, flexibility and stability of the display device may be improved.

In an embodiment, the second adhesive layer AD2 may be in contact with an substantially entire bottom surface of the second portion 320 of the reinforcing structure 300. Accordingly, adhesion stability of the display panel 100 or the cover panel 500, and the connection structure CS may be further improved.

In an embodiment and as illustrated in FIG. 4, a flexible printed circuit (FPC) may be connected under a bottom surface of the cover panel 500. For example, the flexible printed circuit board may be provided as a main circuit board (a main FPC: MFPC) electrically connected to a driving integrated circuit (IC) chip of the display device.

In an embodiment, the display device may be curved. For example, the above-described display device may be provided as a curved display device.

In an embodiment, the stacked structure of the window region 200, the first adhesive layer AD1, the light control region 400, the display panel 100 and/or the cover panel 500 may be bent with a predetermined curvature.

The curved display device may be applied to, e.g., a media device such as a TV, a smartphone or a tablet, or a front window or a dashboard of a vehicle.

According to an embodiment, penetration of cracks, interlayer detachment and/or external impurities due to bending of the stack structure may be reduced or suppressed by the reinforcing structure 300. Thus, mechanical stability may be improved even when the display device is provided as the curved display device to various objects.

In an embodiment, an area of the bezel area BZA may be reduced as an area of the transmissive area TA serving as an image display area increases. In this case, the connection structure CS may not have enough space to cover the lateral surface of the display panel 100 and adjacent layers, and thus the window region 200 and the connection structure CS may be spaced apart from each other as illustrated in FIGS. 2 to 4.

According to an embodiment, the lateral surface may be covered by the above-described reinforcement structure 300 so that structural stability of the display device may be improved while reducing the bezel area BZA.

In an embodiment, the above-described display device may be combined with or included in various types of electronic devices using the connection structure CS. For example, as illustrated in FIG. 4, the display device may be coupled to a frame FR of the electronic device by the connection structure CS.

The electronic device may include a flat panel display, a curved display, a computer monitor, a medical monitor, a television, a billboard, an indoor or outdoor lighting, a signal light, a head-up display, a transparent display, a flexible display, a rollable display, a foldable display, a laser printer, a phone, a mobile phone, a tablet, a phablet, a personal information terminal (PDA), a wearable device, a laptop computer, a digital camera, a camcorder, a viewfinder, a 3D display, an electronic book, an electronic dictionary, an electronic notebook, an electronic sensor, a virtual reality or augmented reality display, a video wall, a theater or a stadium screen, a health care device, a vehicle, etc.

In an embodiment, the window region 200 may be formed on the display panel 100, and the reinforcing structure 300 covering the lateral surface of the display panel 100 and extending under the bottom surface of the display panel 100 may be formed. The reinforcing structure 300 may be formed by applying the above-described resin in a mold shape.

In an embodiment, the light control region 400 may be further formed between the display panel 100 and the window region 200. The light control region 400 and the window region 200 may be stacked via the first adhesive layer AD1.

In an embodiment, the cover panel 500 may be further formed under the bottom surface of the display panel 100.

In an embodiment, the second portion 320 may cover at least a portion of the bottom surface of the cover panel 500.

Moreover, the bottom surface of the second portion 320 and the connection structure CS may be adhered by the second adhesive layer AD2.

FIG. 5 is a cross-sectional view illustrating a display panel, in accordance with an embodiment.

In an embodiment and referring to FIG. 5, the display panel 100 may include a circuit layer CL disposed on a base substrate 102, and light-emitting devices ED1, ED2 and ED3 disposed on the circuit layer CL.

The base substrate 102 may serve as a support substrate or a back-plane substrate of the display panel 100. A glass substrate or a plastic substrate may be used as the base substrate 102.

In an embodiment, the base substrate 102 may include a polymer material having transparency and flexibility. In this case, the base substrate 102 may be used in a transparent flexible display device. For example, the base substrate 102 may include a polymer material such as polyimide, polysiloxane, an epoxy resin, an acrylic resin or polyester. In an embodiment, the base substrate 102 may include polyimide.

In an embodiment, the circuit layer CL may include transistors TR1, TR2 and TR3 and may include wiring layers and insulation layers forming a thin film transistor array TFT-Array.

In an embodiment, the circuit layer CL may further include a buffer layer 104 formed on a top surface of the base substrate 102. Moisture penetrating through the base substrate 102 may be blocked by the buffer layer 104, and diffusion of impurities between the base substrate 102 and structures formed on the base substrate 102 may also be blocked.

In an embodiment, the buffer layer 104 may include, e.g., silicon oxide, silicon nitride or silicon oxynitride. These may be used alone or in a combination of two or more therefrom. In some embodiments, the buffer layer 104 may have a stacked structure including a silicon oxide layer and a silicon nitride layer.

In an embodiment, the transistors TR1, TR2 and TR3 may be disposed on the buffer layer 104. A first transistor TR1, a second transistor TR2 and a third transistor TR3 may be electrically connected to a first light-emitting device ED1, a second light-emitting device ED2 and a third light-emitting device ED3, respectively.

In an embodiment, each of the transistors TR1, TR2 and TR3 may include an active layer 101, a gate insulation layer 103, a gate electrode 105, and connection electrodes 107 and 109.

In an embodiment, the active layer 101 may be disposed on the buffer layer 104 and may be repeatedly/regularly arranged for each pixel. The active layer 101 may include a silicon compound such as polysilicon. A p-type dopant or an n-type dopant may be doped in a partial region of the active layer 101, and may include a source region, a drain region and a channel region.

Additionally, the active layer 101 may include an oxide semiconductor such as indium gallium zinc oxide (IGZO), zinc tin oxide (ZTO) or ITZO.

In an embodiment, the gate insulation layer 103 may be formed on the active layer 101, and the gate electrode 105 may be stacked on the gate insulation layer 103. As illustrated in FIG. 5, the gate insulation layer 103 may be formed in a pattern shape partially covering each active layer 101. In another embodiment, the gate insulation layer 103 may extend continuously over a plurality of pixels or light-emitting regions, and may be included commonly in the transistors TR1, TR2 and TR3.

The gate electrode 105 may overlap the channel region of the active layer 101 in the thickness direction.

In an embodiment, an insulating interlayer 106 covering the gate insulation layer 103 and the gate electrode 105 may be formed on the active layer 101. The connection electrodes 107 and 109 that may be in contact with or electrically connected to the active layer 101 may be disposed on the insulating interlayer 106.

In an embodiment, the connection electrodes 107 and 109 may penetrate the insulating interlayer 106, and may be connected to the active layer 101. When the gate insulation layer 103 is continuously formed commonly in the plurality of the light-emitting regions, the connection electrodes 107 and 109 may also penetrate the gate insulation layer 103.

The connection electrodes 107 and 109 may include a source electrode 107 connected to or in contact with the source region of the active layer 101, and a drain electrode 109 connected to or in contact with the drain region of the active layer 101.

In an embodiment, the gate insulation layer 103 and the insulating interlayer 106 may include silicon oxide, silicon nitride or silicon oxynitride, and may have a stacked structure including a silicon oxide layer and a silicon nitride layer.

In an embodiment, the gate electrode 105 and the connection electrodes 107 and 109 may include a metal such as Ag, Mg, Al, W, Cu, Ni, Cr, Mo, Ti, Pt, Ta, Nd, Sc, an alloy thereof, or a nitride thereof.

In an embodiment, the via insulation layer 108 may be formed on the insulating interlayer 106 to cover the connection electrodes 107 and 109.

The via insulation layer 108 may accommodate a via structure electrically connecting a first electrode 110 to the drain electrode 109. The via insulation layer 108 may serve as a planarization layer of the circuit layer CL. In some embodiments, the via insulation layer 108 may include an organic material such as polyimide, an epoxy resin, an acrylic resin, polyester, etc.

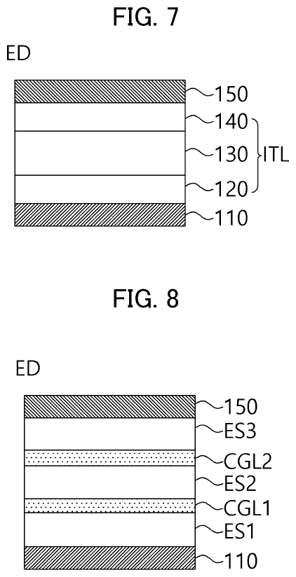

In an embodiment, the light-emitting devices ED1, ED2 and ED3 may be disposed on the via insulation layer 108. Detailed components of the light-emitting device ED will be described later with reference to FIGS. 7 to 11.

In an embodiment, the light emitting devices ED1, ED2 and ED3 may include the first electrode 110, a hole transfer region 120, an emission layer 130, an electron transfer region 140 and a second electrode 150 sequentially stacked from the via insulation layer 108.

The first electrode 110 may be electrically connected to the transistors TR1, TR2 and TR3 or the connection electrodes 107 and 109 included in the circuit layer CL through the via structure. As illustrated in FIG. 5, the first electrode 110 may be in contact with or connected to the drain electrode 109 to serve as a pixel electrode patterned for each light emitting region or pixel region.

In an embodiment, a pixel defining layer 170 may be formed on the via insulation layer 108 to define the light-emitting region or the pixel region. A blue light-emitting region, a red light-emitting region and a green light-emitting region may be separated and defined by the pixel defining layer 170, and the light-emitting devices ED1, ED2 and ED3 may correspond to a blue light-emitting device, a red light-emitting device and a green light-emitting device, respectively.

Additionally, the pixel defining layer 170 may partially cover the first electrode 110 of each light emitting-region.

In an embodiment and as illustrated in FIG. 5, the hole transfer region 120 and the electron transfer region 140 may be formed continuously and commonly on the pixel defining layer 170 and a plurality of the first electrodes 110. The emission layer 130 may be formed in the form of an island shape separated for each light-emitting region or pixel region, and may be limited by the pixel defining layer 170.

In an embodiment, the emission layer 130 may also be commonly and continuously formed over a plurality of the light-emitting regions or the pixel regions. In some embodiments, the hole transfer region 120, the emission layer 130 and the electron transfer region 140 may all be separated and selectively formed for each light-emitting region or the pixel region.

In an embodiment, the second electrode 150 may serve as a common electrode continuously formed over a plurality of the light-emitting regions or the pixel regions.

In an embodiment, an encapsulation layer 180 may be disposed on the pixel defining layer 170 and the light-emitting devices ED1, ED2 and ED3 to protect the light-emitting devices ED1, ED2 and ED3 from moisture or oxygen. The encapsulation layer 180 may be formed as a thin film encapsulation (TFE) having a single-layered structure or a multi-layered structure.

The encapsulation layer 180 may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)) or any combination thereof, or a combination of the organic layer and the inorganic layer.

In an embodiment, the display panel 100 may further include a functional layer 190 disposed on the encapsulation layer 180, where the functional layer 190 may include a sensor layer such as a touch sensor layer or an optical layer such as a polarizing layer, a color conversion layer or a color filter layer.

FIG. 6 is a cross-sectional view illustrating a display panel, in accordance with an embodiment.

FIG. 6 illustrates a display panel 100 having a QD-OLED structure, according to an embodiment. Detailed descriptions of elements and structures substantially the same as or similar to those described with reference to FIG. 5 are omitted.

In an embodiment and referring to FIG. 6, the pixel defining layer 170 and the light-emitting device ED may be disposed on the circuit layer CL as described with reference to FIG. 5. In some embodiments, a light of the same wavelength region may be emitted from each pixel. In an embodiment, a blue light may be emitted from each light emitting device ED.

In some embodiments, a light-emitting device having a tandem structure may be disposed in each light-emitting region. In this case, an intermediate layer included in the light emitting device ED may be commonly and continuously formed over a plurality of the light-emitting regions. The light-emitting device having the tandem structure will be described later with reference to FIG. 8.

In an embodiment, a color control layer CCL including color control portions CCP1, CCP2 and CCP3 may be disposed on the encapsulation layer 180.

The color control portions CCP1, CCP2 and CCP3 may include a light-converter such as a quantum dot or a fluorescent material. A wavelength of a light introduced to each of the color control portions CCP1, CCP2 and CCP3 may be converted and emitted by the light-converter.

The color control portions CCP1, CCP2 and CCP3 may be separated or spaced apart from each other by a bank BM, where the bank BM may substantially overlap the pixel defining layer 170, and the color control portions CCP1, CCP2 and CCP3 may substantially overlap the emission layer 130.

In an embodiment, the color control layer CCL may include the first color control portion CCP1 including a first quantum dot for converting a first color light provided from the light-emitting device ED into a second color light, the second color control portion CCP2 including a second quantum dot for converting the first color light into a third color light, and the third color control portion CCP3 for transmitting the first color light.

In an embodiment, the first color light, the second color light and the third color light may be a blue light, a red light and a green light, respectively. The first quantum dot and the second quantum dot may be a red quantum dot and a green quantum dot, respectively.

In an embodiment, the color control portions CCP1, CCP2 and CCP3 may further include a scattering material such as inorganic particles. The third color control portion CCP3 may not include quantum dots and may include the scattering material, where the scattering material may include TiO₂, ZnO, Al₂O₃, SiO₂, hollow silica, etc. These may be used alone or in combination of two or more therefrom.

In an embodiment, the color control portions CCP1, CCP2 and CCP3 may further include a binder resin for dispersing the quantum dot and the scattering material. The binder resin may include an acrylic resin, a urethane resin, a silicone resin, an epoxy resin, etc.

In an embodiment, a color filter layer CFL including color filters CF1 and CF2 and a light-shielding portion CP may be disposed on the color control layer CCL.

In an embodiment, the color filter layer CFL may include a first filter CF1 that may transmit the second color light, a second filter CF2 that may transmit the third color light, and a third filter that may transmit the first color light. For example, the first filter CF1 may be a red filter, the second filter CF2 may be a green filter, and the third filter may be a blue filter.

The color filters CF1 and CF2 may include a photosensitive binder resin and a colorant material including a pigment and/or dye. The first filter CF1 may include a red pigment or dye, and the second filter CF2 may include a green pigment or dye.

In an embodiment, the light-shielding portion CP may be disposed between the color filters. In some embodiments, the light-shielding portion may include a first light-shielding portion CP1 and a second light-shielding portion CP2 including colorant materials of different colors.

In an embodiment, the first light-shielding portion CP1 may include a blue colorant material, and the second light-shielding portion CP2 may include a red colorant material. In an embodiment, in the blue light-emitting region, a portion of the first light-shielding portion CP1 exposed between the second light-shielding portions CP2 may serve as the blue color filter, and an additional color filter (a third filter) may be omitted.

In an embodiment, a first barrier layer 192 may be disposed between the color control layer CCL and the light-emitting device ED (or the encapsulation layer 180). A second barrier layer 194 may be disposed between the color control layer CCL and the color filter layer CFL.

The barrier layers 192 and 194 may include at least one inorganic layer. For example, the barrier layers 192 and 194 may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or the like.

Additionally, the barrier layers 192 and 194 may have a multi-layered structure further including an organic layer.

Hereinafter, detailed descriptions on the light-emitting device ED of the display panel 100 will be provided.

FIGS. 7 and 8 are cross-sectional views illustrating light-emitting devices, in accordance with embodiments.

In an embodiment and referring to FIG. 7, the light emitting device ED may include the first electrode 110, the second electrode 150 and an intermediate layer ITL disposed between the first electrode 110 and the second electrode 150. The intermediate layer ITL may include the emission layer 130, the hole transfer region 120 and the electron transfer region 140.

In an embodiment, the hole transfer region 120, the emission layer 130, the electron transfer region 140 and the second electrode 150 may be sequentially stacked from a top surface of the first electrode 110.

In an embodiment, the hole transfer region 120 may include a hole injection layer and a hole transport layer. The electron transfer region 140 may include an electron injection layer and an electron transport layer. For example, the hole injection layer, the hole transport layer, the emission layer, the electron transport layer, the electron injection layer and the second electrode may be sequentially stacked from the top surface of the first electrode 110.

In an embodiment, the first electrode 110 may be an anode or a cathode. In some embodiments, the first electrode 110 may serve as the anode and also may serve as a pixel electrode. In this case, the first electrode 110 may include a high work function conductive material that may promote a hole injection.

In an embodiment, the first electrode 110 may be provided as a transmissive electrode and may include a transparent conductive oxide such as indium tin oxide (ITO), indium zinc oxide (IZO), zinc oxide (ZnO), indium tin oxide (ITZO), etc.

In an embodiment, the first electrode 110 may be provided as a transflective electrode or a reflective electrode, where the first electrode 110 may include a metal selected from Ag, Mg, Cu, Al, Pt, Pd, Au, Ni, Nd, Ir, Cr, Li, Ca, LiF, Mo, Ti, W, In, Sn and Zn, or an alloy of two or more thereof. For example, the first electrode 110 may include Li, Ca, LiF/Ca (a stacked structure of LiF and Ca), LiF/Al (a stacked structure of LiF and Al), a mixture of Ag and Mg.

In an embodiment, the first electrode 110 may have a single-layered structure or a multi-layered structure. For example, the first electrode 110 may have a tiple-layered structure of ITO/Ag/ITO.

In an embodiment, a thickness of the first electrode 110 may be in a range from about 700 Å to about 10,000 Å, or from about 1,000 Å to about 3,000 Å.

In an embodiment, the second electrode 150 may serve as a cathode or an anode. In some embodiments, the second electrode 150 may serve as an electron injection electrode or the cathode. The second electrode 150 may include a metal, an alloy, an electrically conductive compound, etc., having a low work function.

For example, the second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, etc. These may be used alone or in combination of two or more therefrom.

In an embodiment, the second electrode 150 may be provided as a transmissive electrode, a transflective electrode, or a reflective electrode and the second electrode 150 may have a single-layered structure or a multi-layered structure.

In an embodiment, the emission layer 130 may include a host material. For example, the emission layer 130 may include a widely known host material in the related art such as an anthracene derivative, a pyrene derivative, a fluoranthene derivative, a chrysene derivative, a dihydrobenzanthracene derivative, a triphenylene derivative, etc.

In an embodiment, the emission layer 130 may include a fluorescent host material and/or a phosphorescent host material.

The emission layer 130 may include, e.g., BCPDS (bis(4-(9H-carbazol-9-yl) phenyl) diphenylsilane), POPCPA ((4-(1-(4-(diphenylamino) phenyl) cyclohexyl) phenyl) diphenyl-phosphine oxide), DPEPO (bis[2-(diphenylphosphino)phenyl] ether oxide), mCBP (3,3′-di(9H-carbazol-9-yl)-1,1′-biphenyl), CBP (4,4′-bis(N-carbazolyl)-1,1′-biphenyl), mCP (1,3-bis(carbazol-9-yl)benzene), PPF (2,8-bis(diphenylphosphoryl)dibenzo[b,d]furan), TCTA (4,4′,4″-Tris(carbazol-9-yl)-triphenylamine), TPBi (1,3,5-tris(1-phenyl-1H-benzo[d]imidazole-2-yl)benzene), Alq3 (tris(8-hydroxyquinolino)aluminum), AND (9,10-di(naphthalene-2-yl)anthracene), TBADN (2-tert-butyl-9,10-di(naphth-2-yl)anthracene), DSA (distyrylarylene), CDBP (4,4′-bis(9-carbazolyl)-2,2′-dimethyl-biphenyl), MADN (2-methyl-9,10-bis(naphthalen-2-yl)anthracene), CP1 (mexaphenyl cyclotriphosphazene), UGH2 (1,4-bis(triphenylsilyl)benzene), DPSiO3 (hexaphenylcyclotrisiloxane), DPSiO4 (octaphenylcyclotetrasiloxane), etc., as the host material. Theses may be used alone or in a combination of two or more therefrom.

Additionally, the emission layer 130 may further include a dopant interacting with the above-described host material.

In an embodiment, the emission layer 130 may include a fluorescent dopant and/or a phosphorescent dopant.

In some embodiments, the emission layer 130 may include, e.g., a styryl derivative (e.g., 1,4-bis[2-(3-nethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (NBDAVBi)), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), etc., as the fluorescent dopant material.

In an embodiment, the emission layer 130 may include a metal complex including iridium (Ir), platinum (Pt), osmium (Os), gold (Au), titanium (Ti), zirconium (Zr), hafnium (Hf), europium (Eu), terbium (Tb), or thulium (Tm) as the phosphorescent dopant. For example, FIrpic (iridium (III) bis(4,6-difluorophenylpyridinato-N,C2′)picolinate), FIr6 (Bis(2,4-difluorophenylpyridinato)-tetrakis(1-pyrazolyl)borate iridium (III)), PtOEP (platinum octaethyl porphyrin), etc., may be used as the phosphorescent dopant.

In an embodiment, the emission layer 130 may include a boron-containing dopant.

The above-described dopant materials may be used alone or in a combination of two or more therefrom.

In an embodiment, the emission layer 130 may include two or more host materials. For example, the emission layer 130 may include a hole-transporting host and an electron-transporting host. In this case, the emission layer 130 may include the hole-transporting host, the electron-transporting host, a photosensitizer and a dopant. In some embodiments, the hole-transporting host and the electron-transporting host may form an exciplex, and energy transfer from the exciplex to the photosensitizer, and from the photosensitizer to the dopant may occur, thereby inducing a light-emission.

In an embodiment, the emission layer 130 may include a quantum dot, where the quantum dot may include a group II-VI compound, a group III-VI compound, a group I-III-VI compound, a group III-V compound, a group III-II-V compound, a group IV-VI compound, a group IV element, a group IV compound, or a combination thereof.

In an embodiment, the hole transfer region 120 may include m-MTDATA (4,4′,4″-[tris(3-methylphenyl)phenylamino]triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalene-1-yl)-N,N′-diphenyl-benzidine), TPD (N,N′-bis(3-methylphenyl)-N,N′-diphenyl-[1,1′-biphenyl]-4,4′-diamine), Spiro-TPD, Spiro-NPB, DNTPD (N¹,N^{1′}-([1,1′-biphenyl]-4,4′-diyl)bis(N¹-phenyl-N⁴,N⁴-di-m-tolylbenzene-1,4-diamine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), TCTA (4,4′,4″-tris(N-carbazolyl)triphenylamine), PANI/DBSA (polyaniline/Dodecylbenzenesulfonic acid), PEDOT/PSS (Poly(3,4-ethylenedioxythiophene)/Poly(4-styrenesulfonate)), PANI/CSA (Polyaniline/Camphor sulfonicacid), PANI/PSS (polyaniline/poly(4-styrenesulfonate)), a phthalocyanine-based compound, a carbazole-based compound (N-phenylcarbazole, polyvinylcarbazole, etc.), a fluorene-based compounds, etc. These may be used alone or in combination of two or more therefrom.

In an embodiment, the hole transfer region 120 may further include a charge generating material. A dopant material such as a p-dopant may be used as the charge generating material, and thus a conductivity of the hole transfer region 120 may be improved.

Examples of the dopant materials include a halogenated metal compound such as LiF, NaCl, CsF, RbCl, Rbl, CuI, KI, etc.; a quinone derivative such as TCNQ (tetracyanoquinodimethane), F4-TCNQ (2,3,5,6-tetrafluoro-7,7,8,8-tetracyanoquinodimethane), etc., a cyano-containing compound such as HATCN (dipyrazino[2,3-f: 2′,3′-h] quinoxaline-2,3,6,7,10,11-hexacarbonitrile), NDP9 (4-[[2,3-bis[cyano-(4-cyano-2,3,5,6-tetrafluorophenyl)methylidene]cyclopropylidene]-cyanomethyl]-2,3,5,6-tetrafluorobenzonitrile), a W oxide, a Mo oxide, etc. These may be used alone or in a combination of two or more therefrom.

The electron transfer region 140 may include an anthracene compound, Alq3 (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, TPBi (1,3,5-Tri (1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (Bis(2-methyl-8-quinolinolato-N1,O8)-(1,1′-biphenyl-4-olato)aluminum), Bebq₂ (beryllium bis(benzoquinolin-10-olate)), AND (9,10-di(naphthalene-2-yl)anthracene), BmPyPhB (1,3-bis[3,5-di(pyridin-3-yl)phenyl]benzene), etc. These may be used alone or in a combination of two or more therefrom.

In an embodiment, the electron transfer region 140 may include an alkali metal, an alkaline earth metal, a rare earth metal, an alkali metal-containing compound, an alkaline earth metal-containing compound, a rare earth metal-containing compound, an alkali metal complex, an alkaline earth metal complexes, a rare earth metal complexes, or a combination thereof. In an embodiment, the above-described materials may be included in the electron injection layer.

The alkali metal may include Li, Na, K, Rb, Cs or an any combination thereof. The alkaline earth metal may include Mg, Ca, Sr, Ba or an any combination thereof. The rare earth metal may include Sc, Y, Ce, Tb, Yb, Gd or any combination thereof.

In an embodiment, the alkali metal-containing compound, the alkaline earth metal-containing compound and the rare earth metal-containing compound may include an oxide, a halide (e.g., a fluoride, a chloride, a bromide, an iodide, etc.), a telluride, or a combination thereof of the alkali metal, the alkaline earth metal and the rare earth metal, respectively.

In an embodiment, the alkali metal complex, the alkaline earth metal complex and the rare earth metal complex may include a metal ion of the alkali metal, the alkaline earth metal or the rare earth metal, and a ligand bonded to the metal ion. The ligand may include, e.g., hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzoimidazole, hydroxyphenylbenzothiazole, bipyridine, phenanthroline, cyclopentadiene or a combination thereof.

In an embodiment and referring to FIG. 8, the light-emitting device ED may include a plurality of light-emitting structures ES1, ES2 and ES3. Each of the light-emitting structures ES1, ES2 and ES3 may include a stacked structure of the hole transport region 120, the emission layer 130 and the electron transport region 140 as described with reference to FIG. 7. In some embodiments, the light-emitting device ED of FIG. 8 may be a light-emitting device having a tandem structure.

In an embodiment, the charge generation layers CGL1 and CGL2 may be disposed between neighboring light-emitting structures ES1, ES2 and ES3. The charge generation layers CGL1 and CGL2 may include a p-type charge generation layer and/or an n-type charge generation layer. The charge generation layers CGL1 and CGL2 may include a first charge generation layer CGL1 disposed between the first light-emitting structure ES1 and the second light-emitting structure ES2, and a second charge generation layer CGL2 disposed between the second light-emitting structure ES2 and the third light-emitting structure ES3.

In an embodiment, the first light-emitting structure ES1, the first charge generation layer CGL1, the second light-emitting structure ES2, the second charge generation layer CGL2, the third light-emitting structure ES3 and the second electrode 150 may be sequentially stacked from the top surface of the first electrode 110.

In some embodiments, the light-emitting device ED may be applied to an organic light emitting diode (OLED) display device or a quantum dot (QD)-OLED display device.

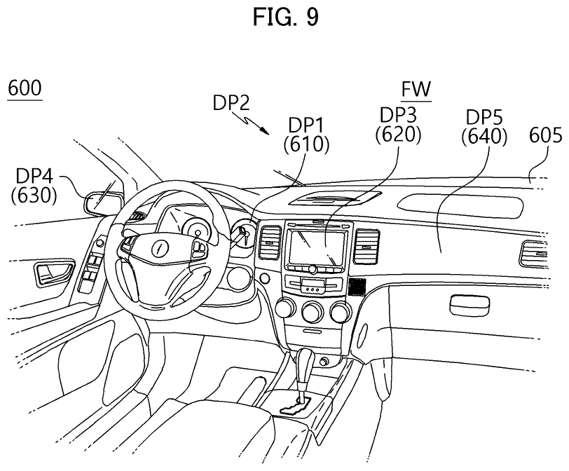

FIG. 9 is a view illustrating a vehicle to which a display device is employed, according to an embodiment.

In an embodiment and referring to FIG. 9, the vehicle 600 may include a vehicle frame 605 and the above-described display device coupled to the vehicle frame 605.

The vehicle frame 605 may refer to a material constructing a vehicle body and/or a shape of the vehicle 600.

For example, the display device may be coupled to the vehicle frame 605 using the connection structure CS. For example, the connection structure CS may be provided as an intermediate structure connecting the display device and the vehicle 600.

In an embodiment and as illustrated in FIG. 9, at least one of the display devices DP1, DP2, DP3 and DP4 may be applied to the vehicle 600.

In some embodiments, the first display device DP1 may be disposed in a cluster area 610, where driving information such as a driving distance and a speed, and various warning lights may be displayed in the cluster area 610.

The second display device DP2 may be disposed on a front window FW of the vehicle 600. For example, the second display device DP2 may be installed in the form of a head-up display (HUD).

The third display device DP3 may be disposed on a center fascia area 620 of the vehicle 600, where in the center fascia area 620, a button or a switch for controlling operations of an image/music player, an air conditioner, a heater, etc., may be displayed, and vehicle information may be displayed.

The fourth display device DP4 may be applied to a side mirror 630 of the vehicle 600, where the side mirror 630 may be installed on both sides of an outside of the vehicle, and where the fourth display device DP4 may be applied to at least one of the side mirrors 630.

The fifth display device DP5 may be disposed on a passenger seat dashboard 640, where information/image identical to or different from information/image displayed on the cluster area 610 and/or the center fascia area 620 may be displayed from the passenger seat dashboard 640.

It will be understood by one of ordinary skill in the art to which the invention belongs that the invention may be implemented in other specific embodiments than those described herein without changing the technical spirit or essential features of the invention. Therefore, it is to be understood that the exemplary embodiments described above are illustrative rather than being restrictive in all aspects. The disclosed embodiments of the invention are used in a generic and descriptive sense only and not for purposes of limitation. Each component specifically shown in the embodiments of the invention can be implemented by modification, and such modifications and differences related to invention should be construed as being included in the scope of the invention. Moreover, the embodiments or parts of the embodiments may be combined in whole or in part without departing from the scope of the invention.

What is claimed is:

1. A display device, comprising:
a display panel;
a window region disposed on a top surface of the display panel; and
a reinforcing structure comprising:
a first portion covering a lateral surface of the display panel; and
a second portion disposed under a bottom surface of the display panel.

2. The display device according to claim 1, wherein the window region comprises:
a window substrate including a transmissive area and a bezel area; and
a light-shielding pattern arranged under the bezel area.

3. The display device according to claim 2, wherein the first portion covers at least a portion of a bottom surface of the light-shielding pattern.

4. The display device according to claim 1, further comprising a light control region disposed between the display panel and the window region.

5. The display device according to claim 4, wherein the first portion covers a lateral surface of the light control region.

6. The display device according to claim 4, wherein the light control region includes an anti-reflection layer.

7. The display device according to claim 1, further comprising a first adhesive layer disposed between the display panel and the window region.

8. The display device according to claim 7, wherein the first portion covers a lateral surface of the first adhesive layer.

9. The display device according to claim 1, further comprising a second adhesive layer and a connection structure sequentially arranged under a bottom surface of the second portion.

10. The display device according to claim 9, wherein the second adhesive layer contacts the bottom surface of the second portion and does not contact the display panel.

11. The display device according to claim 1, further comprising a cover panel arranged under the bottom surface of the display panel,
wherein the second portion covers at least a portion of a bottom surface of the cover panel.

12. The display device according to claim 11, further comprising a second adhesive layer and a connection structure sequentially arranged under a bottom surface of the second portion,
wherein the second adhesive layer is disposed directly under the bottom surface of the second portion and does not contact the cover panel.

13. The display device according to claim 1, wherein the reinforcing structure comprises a resin comprising at least one selected from the group consisting of a Si-based compound and an acrylic-based compound.

14. The display device according to claim 1, wherein the display panel comprises:
a base substrate;
a circuit layer disposed on the base substrate; and
a light-emitting device electrically connected to the circuit layer.

15. The display device according to claim 14, wherein the light-emitting device comprises:
a first electrode;
a second electrode; and
an intermediate layer comprising an emission layer disposed between the first electrode and the second electrode.

16. An electronic device, comprising:
an electronic device frame; and
a display device coupled to the electronic device frame,
where the display device includes,
a display panel;
a window region disposed on a top surface of the display panel; and
a reinforcing structure comprising:
a first portion covering a lateral surface of the display panel; and
a second portion disposed under a bottom surface of the display panel.

17. The electronic device according to claim 16, wherein the display device further comprises a second adhesive layer and a connection structure sequentially arranged under a bottom surface of the second portion, and
the display device is coupled to the electronic device frame by the connection structure.

18. The electronic device according to claim 16, wherein the electronic device includes at least one of a flat panel display, a curved display, a computer monitor, a medical monitor, a television, a billboard, an indoor or outdoor lighting, a signal light, a head-up display, a transparent display, a flexible display, a rollable display, a foldable display, a laser printer, a phone, a mobile phone, a tablet, a phablet, a personal information terminal (PDA), a wearable device, a laptop computer, a digital camera, a camcorder, a viewfinder, a 3D display, an electronic book, an electronic dictionary, an electronic notebook, an electronic sensor, a virtual reality or augmented reality display, a video wall, a theater or a stadium screen, or a health care device.

19. A vehicle, comprising:
a vehicle frame; and
a display device coupled to the vehicle frame,
where the display device includes,
a display panel;
a window region disposed on a top surface of the display panel; and
a reinforcing structure comprising:
a first portion covering a lateral surface of the display panel; and
a second portion disposed under a bottom surface of the display panel.

20. The vehicle according to claim 19, wherein the display device further comprises a second adhesive layer and a connection structure sequentially arranged under a bottom surface of the second portion, and
wherein the display device is coupled to the vehicle frame by the connection structure.
